(19) United States
(12) Patent Application Publication
(10) Pub. No.: US 2026/0148766 A1
(43) Pub. Date: May 28, 2026

(54) MEMORY DEVICE INCLUDING NEGATIVE VOLTAGE GENERATOR

(71) Applicant: Samsung Electronics Co., Ltd., Suwon-si (KR)

(72) Inventors: Hoyoung Tang, Suwon-si (KR); HOON KIM, Suwon-si (KR); Hyunjun Kim, Suwon-si (KR)

(21) Appl. No.: 19/224,873

(22) Filed: Jun. 1, 2025

(30) Foreign Application Priority Data
Nov. 27, 2024 (KR) 10-2024-0171738

(51) Int. Cl. G11C 11/419

(52) U.S. Cl. CPC G11C 11/419

(57) ABSTRACT

A memory device includes first and second memory cells, a first write driver configured to provide write data to the first memory cell, a second write driver configured to provide write data to the second memory cell, and a negative voltage generator configured to provide a negative voltage to the first and second write drivers. The negative voltage generator includes a first coupling capacitor configured to provide the negative voltage to the first write driver, and a second coupling capacitor configured to provide the negative voltage to the second write driver. The first and second coupling capacitors are electrically connected to one another.

### CROSS-REFERENCE TO RELATED APPLICATION(S)

This application claims priority under 35 U.S.C. § 119 to Korean Patent Application No. 10-2024-0171738 filed on Nov. 27, 2024, in the Korean Intellectual Property Office, the disclosure of which is incorporated by reference herein in its entirety.

### BACKGROUND

Example embodiments of the present disclosure described herein relate to a semiconductor memory device, and more specifically, to a memory device including a negative voltage generator.

Semiconductor memories may be classified as a volatile memory or a non-volatile memory, for example. Typically, the volatile memories (e.g., a dynamic random access memory (DRAM) or a static random access memory (SRAM)) may exhibit faster read and/or write speeds when compared to the non-volatile memory. However, data stored in the volatile memory may disappear when the power applied to the volatile memory is turned off. In contrast, the non-volatile memory may retain the data even when the power is turned off.

A memory cell of an SRAM device can encounter instable write operations due to a number of factors, including process variation that may occur during a fabrication process thereof. In addition, as semiconductor process technology becomes more refined, the resistance of metals continues to increase. If the resistance of bit lines of SRAM devices increases, low-voltage write operations may be deteriorated.

In general, SRAM devices use a write assist technique that applies negative voltage to bit lines connected to memory cells using a negative voltage generator. When SRAM devices provide negative voltage for stable write operations, there is a need to provide a higher negative voltage in the negative direction, which needs a number of capacitors with a large area.

### SUMMARY

Example embodiments of the present disclosure provide a memory device or static random access memory device including a negative voltage generator that may provide a higher negative voltage in the negative direction.

According to an embodiment, a memory device includes first and second memory cells, a first write driver configured to provide write data to the first memory cell, a second write driver configured to provide write data to the second memory cell, and a negative voltage generator configured to provide a negative voltage to the first and second write drivers. The negative voltage generator includes a first coupling capacitor configured to provide the negative voltage to the first write driver, and a second coupling capacitor configured to provide the negative voltage to the second write driver. The first and second coupling capacitors are electrically connected to one another.

According to an embodiment, a memory device includes a memory cell, a first bit line connected to the memory cell, a second bit line connected to the memory cell, a write driver including a first inverter configured to provide write data to the memory cell through the first bit line and a second inverter configured to provide write data to the memory cell through the second bit line, and a negative voltage generator configured to provide a negative voltage to the write driver. The negative voltage generator includes a first coupling capacitor configured to provide the negative voltage to the first inverter, and a second coupling capacitor configured to provide the negative voltage to the second inverter. The first and second coupling capacitors are electrically connected to one another.

According to an embodiment, a memory device includes first and second memory cells, first and second bit lines connected to the first memory cell, third and fourth bit lines connected to the second memory cell, a first write driver including a first inverter configured to provide write data to the first memory cell through the first bit line, and a second inverter configured to provide write data to the first memory cell through the second bit line, a second write driver including a third inverter configured to provide write data to the second memory cell through the third bit line, and a fourth inverter configured to provide write data to the second memory cell through the fourth bit line, and a negative voltage generator configured to provide a negative voltage to the first and second write drivers. The negative voltage generator includes a first coupling capacitor configured to provide the negative voltage to the first inverter, a second coupling capacitor configured to provide the negative voltage to the second inverter, a third coupling capacitor configured to provide the negative voltage to the third inverter, and a fourth coupling capacitor configured to provide the negative voltage to the fourth inverter. The first to fourth coupling capacitors are electrically connected to one another.

### BRIEF DESCRIPTION OF THE FIGURES

The above and other objects and features of the present disclosure will become apparent by describing in detail embodiments thereof with reference to the accompanying drawings.

FIG. 1 is a block diagram illustrating a static random access memory device according to example embodiments.

FIGS. 2 and 3 are timing diagrams for explaining a write operation through the write driver illustrated in FIG. 1.

FIG. 4 is a block diagram illustrating a storage device that applies a negative voltage using the write assist technique according to example embodiments.

FIG. 5 is a block diagram illustrating a memory device illustrated in FIG. 4 according to example embodiments.

FIG. 6 is a circuit diagram illustrating a memory cell array illustrated in FIG. 5 according to example embodiments.

FIG. 7 is a block diagram illustrating a memory device illustrated in FIG. 5 according to example embodiments.

FIG. 8 is a circuit diagram for explaining a write assist operation using a negative voltage generator of the memory device illustrated in FIG. 7 according to example embodiments.

FIG. 9 is a timing diagram illustrating a negative voltage level of the memory device illustrated in FIG. 8 according to example embodiments.

FIG. 10 is a block diagram illustrating a memory device according to an example embodiment of the present disclosure.

FIG. 11 is a timing diagram illustrating a negative voltage level of the memory device illustrated in FIG. 10 according to example embodiments.

FIG. 12 is a block diagram illustrating a memory device according to example embodiments of the present disclosure.

FIG. 13 is a timing diagram illustrating a negative voltage level of the memory device illustrated in FIG. 12 according to example embodiments.

FIG. 14 and FIG. 15 are layout diagrams illustrating a memory device according to example embodiments of the present disclosure.

FIG. 16 is a timing diagram illustrating a negative voltage level of the memory device illustrated in FIGS. 14 and 15 according to example embodiments.

FIG. 17 is a block diagram illustrating a memory device according to example embodiments of the present disclosure.

### DETAILED DESCRIPTION

Below, example embodiments of the present disclosure will be described in detail and clearly to such an extent that an ordinary one in the art easily implements the inventive concepts.

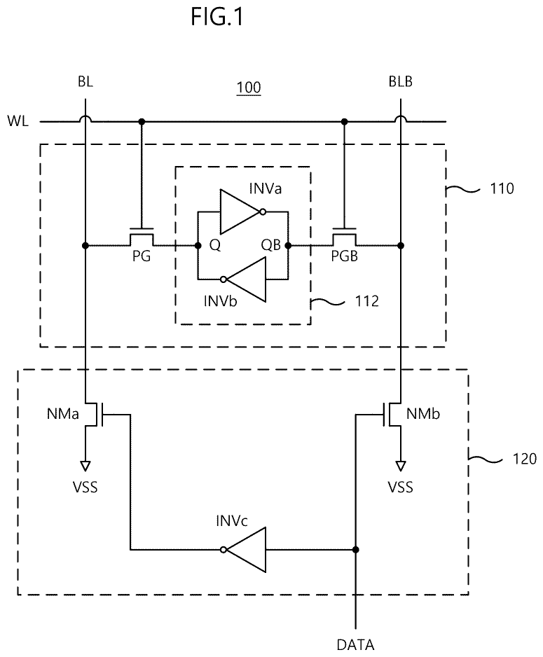

FIG. 1 is a block diagram illustrating a static random access memory (SRAM) device according to example embodiments. Referring to FIG. 1, a SRAM device 100 may include a memory cell 110 and a write driver 120.

The write driver 120 may provide data to the memory cell 110. The write driver 120 may float one bit line among a first bit line BL or a second bit line BLB in response to data signal DATA and provide write data to the remaining bit line. Herein, the second bit line BLB may be referred to as a complementary bit line BLB.

For example, when data signal DATA is a logic high state signal, the first bit line BL may be floated and the second bit line BLB may be provided with write data. Here, the voltage level of the floated bit line may be a logic high voltage, and the write voltage level may be a logic low voltage.

The memory cell 110 may include a latch circuit 112 composed of inverters (INVa and INVb) and pass gates (PG and PGB). In addition, the write driver 120 may include write transistors (NMa and NMb) and an inverter INVc for floating one of the first and second bit lines (BL and BLB) and applying a write voltage to the other.

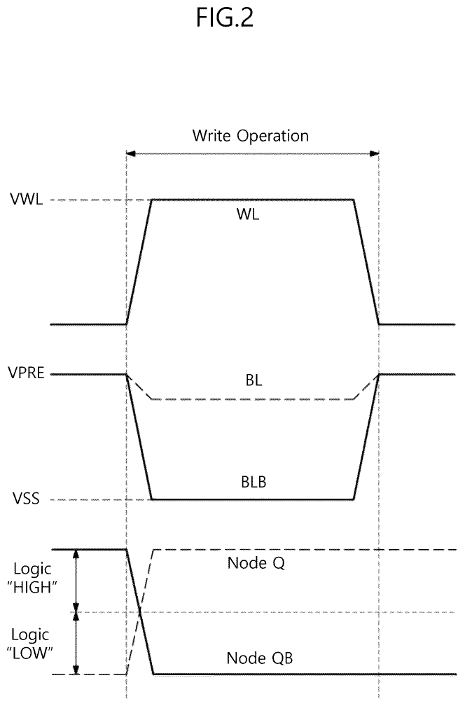

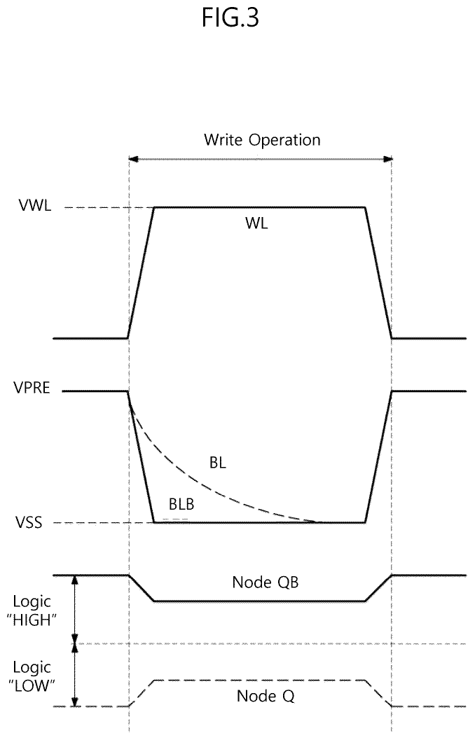

FIGS. 2 and 3 are timing diagrams for explaining a write operation through the write driver illustrated in FIG. 1. FIG. 2 illustrates a case where the write operation is successfully performed, and FIG. 3 illustrates a case where the write operation fails. Hereinafter, the write operation of the SRAM device 100 will be described in further detail with reference to FIGS. 1 to 3.

A data value stored in a first data node Q is a reference of a time at which data is written into the memory cell 110. That is, for purpose of the present discussion, let it be assumed that when a logic state of the first data node Q is logic ‘high’, logic-high data is stored in the memory cell 110.

A write operation described hereinafter will be described based on an operation to write logic-high data into the memory cell 110. It is assumed that, prior to the write operation, a first data node Q is logic ‘low’ and a second data node QB is logic ‘high’. In addition, prior to the write operation, a first bit line BL and a second bit line BLB are precharged to a precharge voltage VPRE.

With reference to FIGS. 1 and 2, a description will now be made with respect to a case where a write operation is successfully performed. When a word line voltage VWL is applied to a word line WL, a first pass gate PG and a second pass gate PGB are turned on. Thus, the first bit line BL and the first data node Q are electrically connected to each other and the second bit line BLB and the second data node QB are electrically connected to each other.

The write driver 120 receives a logic-high data signal DATA. A second write transistor NMb is turned on in response to the data signal DATA having the logic high voltage. The second write transistor NMb drives the second bit line BLB to a ground voltage level. Herein, for convenience of description, the terms of the ground voltage level, a ground, a ground voltage, VSS, 0V, and GND may be used interchangeably. A voltage level of the logic-high second data node QB decreases to the ground.

In the meantime, a first write transistor NMa is turned off in response to an output signal of an inverter INVc. Thus, the first bit line BL is floated. Due to a difference in voltage between the first bit line BL and the first data node Q, current flows from the first bit line BL to the first data node Q to decrease the voltage of the first bit line BL. However, since the voltage of the second node QB is made equal to a voltage of the second bit line BLB driven to the ground, voltage drop of the first data node Q is prevented. For example, the inverter INVb may drive the first data node Q to have the logic high voltage.

When the write operation is successfully performed, the voltage level of each bit line and a voltage level of a data node connected to each bit line are made equal to each other. Thus, the decreased amount of the voltage of the floated first bit line BL is significantly reduced. That is, when the write operation is successfully performed, the logic state of the floated bit line does not change. From the description of FIG. 2, it may be seen that when the write operation is successfully performed, the decreased amount of the voltage of the first bit line BL is relatively small.

Referring to FIGS. 1 and 3, a description will now be presented with respect to a case where a write operation fails. Failure of a write operation may mean that the logic state of a data node of the memory cell does not change even when a write driver applies a voltage corresponding to a logic state that a write driver desires to write into the memory cell.

As described above, the write driver 120 floats the first bit line BL and drives the second bit line BLB to the ground. However, the logic states of the first data node Q and the second data node QB are maintained at previous logic states due to deterioration of the operating characteristics of the memory cell. Thus, the first data node Q is maintained at a logic-low voltage.

Accordingly, current continues to flow from the first bit line BL to the first data node Q due to a voltage difference, which causes the voltage of the first bit line BL to decrease. From the timing diagram of FIG. 3, it can be seen that the logic states of the first data node Q and the second data node QB do not change. In addition, it can be seen that the voltage of the first bit line BL continues to decrease to the logic low voltage. As described above, the voltage of a floated bit line does not substantially change when a write operation is successfully performed. But a voltage change is great when the write operation fails.

The failure of the write operation may occur when the operating characteristics of the memory cell deteriorate during the semiconductor process. For example, as the semiconductor process technology is miniaturized, the resistance of the metal is continuously increasing. If the BL and BLB resistance of the SRAM device 100 increases, the low voltage write operation may be failed. To overcome this, the SRAM device 100 may use a write assist technique that applies a negative voltage to the BL or BLB connected to the memory cell 110 using a negative voltage generator.

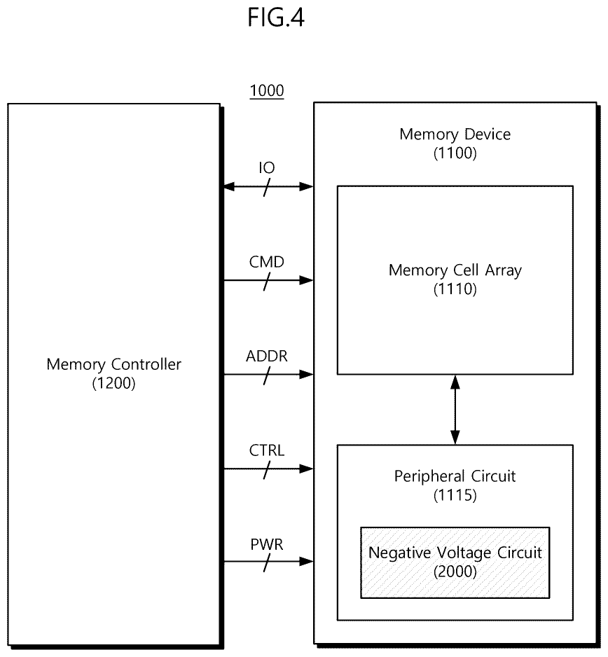

FIG. 4 is a block diagram illustrating a storage device that applies a negative voltage using the write assist technique according to example embodiments. Referring to FIG. 4, a storage device 1000 may include a memory device 1100 and a memory controller 1200.

The memory device 1100 may receive input/output signals IO from the memory controller 1200 through input/output lines, receive control signals CTRL through control lines, and receive external power PWR through power lines. In addition, the memory device 1100 may receive a command CMD and an address ADDR. The storage device 1000 may store data in the memory device 1100 through the control of the memory controller 1200.

The memory device 1100 may include a memory cell array 1110 and a peripheral circuit 1115. The memory cell array 1110 may have a planar two-dimensional structure or a vertical three-dimensional structure. The memory cell array 1110 may include a plurality of memory cells. The memory cell array 1110 may be located (e.g., disposed) next to or above the peripheral circuit 1115 in terms of the design layout structure. The peripheral circuit 1115 may include all analog circuits or digital circuits required to store data in the memory cell array 1110 or read data stored in the memory cell array 1110. The peripheral circuit 1115 may receive the external power PWR through power lines and generate internal powers of various levels.

The peripheral circuit 1115 may input data from the memory controller 1200 through input/output lines. The peripheral circuit 1115 may store data in the memory cell array 1110 according to the control signals CTRL. In addition, the peripheral circuit 1115 may read data stored in the memory cell array 1110 and provide read data to the memory controller 1200.

The peripheral circuit 1115 may include a negative voltage generator 2000 to use a write assist technique. The negative voltage generator 2000 may include a plurality of coupling capacitors for generating negative voltages. The negative voltage generator 2000 may electrically connect a plurality of capacitors to increase the capacitive coupling effect.

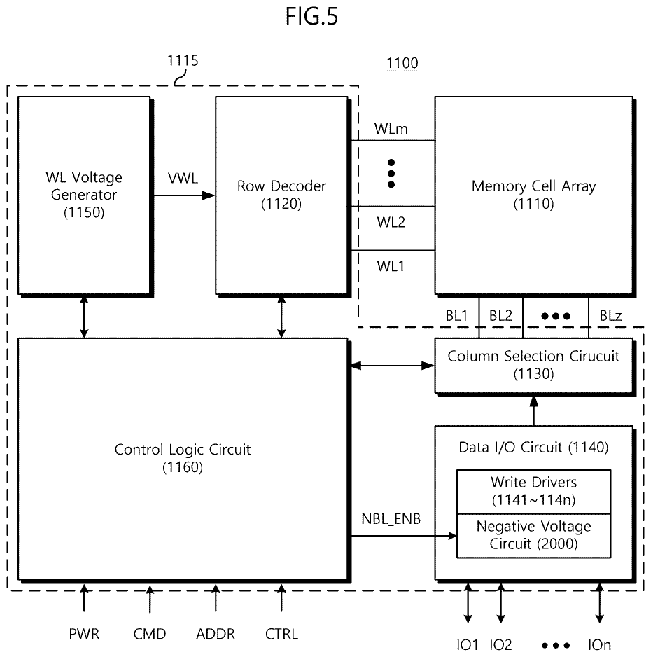

FIG. 5 is a block diagram illustrating the memory device illustrated in FIG. 4 according to example embodiments. Referring to FIG. 5, the memory device 1100 may include a memory cell array 1110 and a peripheral circuit 1115. The peripheral circuit 1115 may include a row decoder 1120, a column selection circuit 1130, a data input/output circuit 1140, a word line voltage generator 1150, and a control logic circuit 1160.

The memory cell array 1110 may be connected to a plurality of word lines WL1 to WLm, m is a natural number equal to or greater than 2. The row decoder 1120 may be connected to the memory cell array 1110 through a plurality of word lines WL1 to WLm. The row decoder 1120 may select a word line during a write or read operation. The row decoder 1120 may receive a word line voltage VWL from the word line voltage generator 1150 and provide a word line voltage VWL for a write or read operation to the selected word line.

The column selection circuit 1130 may be connected to the memory cell array 1110 through first to z-th bit lines BL1 to BLz, z is a natural number equal to or greater than 2. The column selection circuit 1130 may select one or more bit lines in response to control signals provided from the control logic circuit 1160.

The data input/output circuit 1140 may be internally connected to the column selection circuit 1130 through data lines and externally connected to the memory controller 1200 through input/output lines IO1 to IOn. The data input/output circuit 1140 may receive write data from the memory controller 1200 during a write operation.

The data input/output circuit 1140 may provide data read from the memory cell array 1110 to the memory controller 1200 during a read operation. The data input/output circuit 1140 may output data through input/output lines. The number of input/output lines may vary depending on the type of the storage device 1000.

The data input/output circuit 1140 may include first to n-th write drivers 1141 to 114n and a negative voltage generator 2000, n is a natural number equal to or greater than 2. The negative voltage generator 2000 may receive a control signal NBL_ENB signal from the control logic circuit 1160. The negative voltage generator 2000 may include a plurality of coupling capacitors for generating a negative voltage. The negative voltage generator 2000 may provide a negative voltage to the first to n-th write drivers 1141 to 114n. The negative voltage generator 2000 may electrically connect a plurality of capacitors to increase the capacitive coupling effect.

The word line voltage generator 1150 may receive internal power from the control logic circuit 1160 and generate a word line voltage VWL required to read or write data. The word line voltage VWL may be provided to the selected word line through the row decoder 1120.

The control logic circuit 1160 may control operations such as reading and/or writing of the memory device 1100 by using commands CMD, addresses ADDR, and control signals CTRL provided from the memory controller 1200. The addresses ADDR may include a row address for selecting a word line of the word lines and a column address for selecting a bit line of the bit lines.

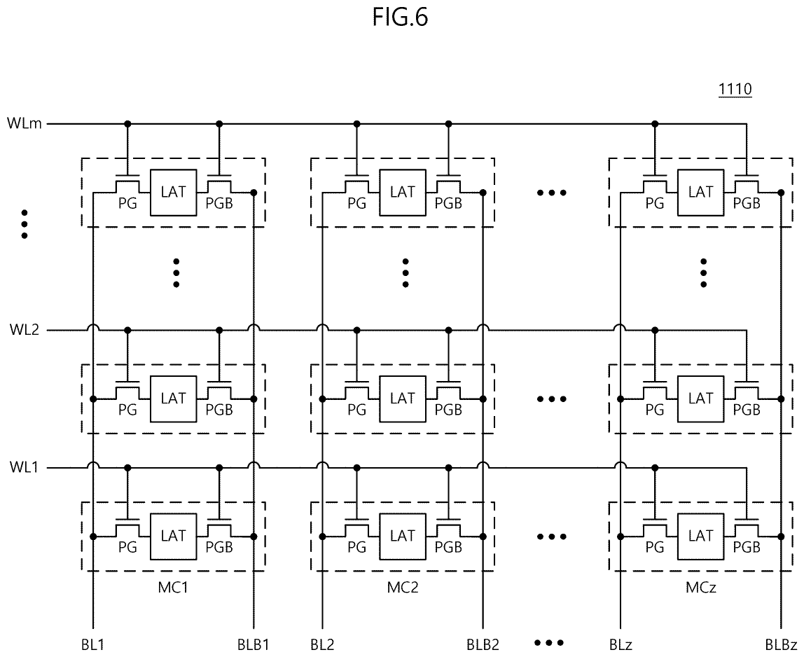

FIG. 6 is a circuit diagram illustrating the memory cell array illustrated in FIG. 5 according to example embodiments. Referring to FIG. 6, the memory cell array 1110 may include a plurality of memory cells (e.g., MC1 to MCz). Each memory cell may be a SRAM cell.

The memory cell array 1110 may be connected to the row decoder 1120 through the first to m-th word lines (WL1 to WLm). The memory cell array 1110 may be connected to the column selection circuit 1130 through the first to z-th bit lines BL1 to BLz and first to z-th complementary bit lines BLB1 to BLBz. Here, BLB1 to BLBz may have voltage levels complementary to BL1 to BLz. For example, if the first bit line BL1 is at the logic high voltage, the first complementary bit line BLB1 may be at the logic low voltage.

Each memory cell of the memory cell array 1110 may include a latch circuit LAT composed of inverters and pass gates PG and PGB. For example, the first memory cell MC1 may be connected to the first word line WL1 and the first bit line and the first complementary bit line BL1 and BLB1. The first word line WL1 may be connected to the gates of the first and second pass gates PG and PGB. The first bit line and the first complementary bit line may be connected to the drains or sources of the first and second pass gates PG and PGB.

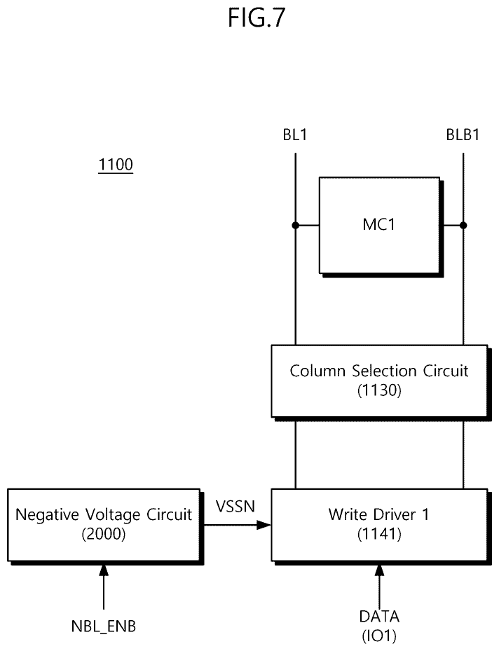

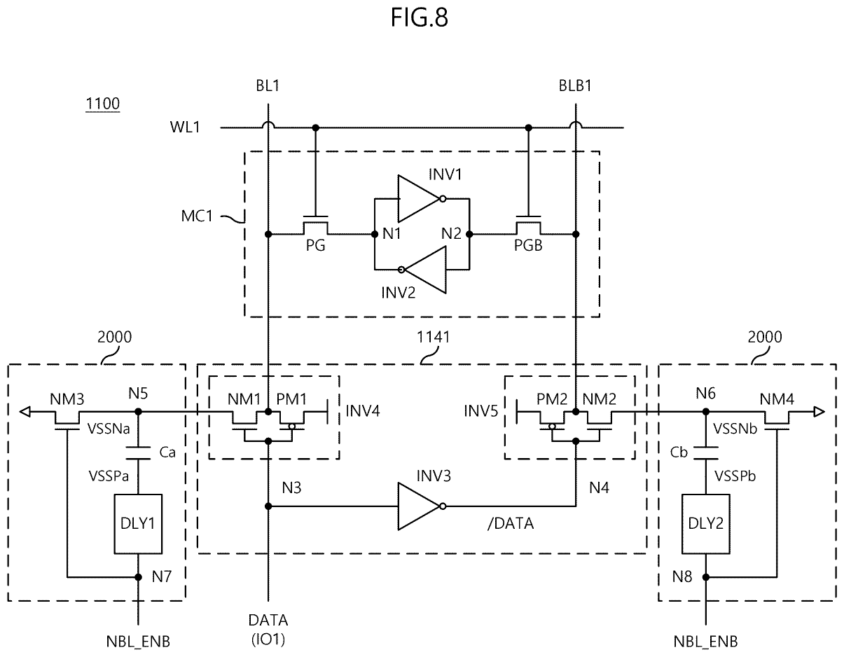

FIG. 7 is a block diagram illustrating the memory device illustrated in FIG. 5 according to example embodiments. FIG. 8 is a circuit diagram for explaining a write assist operation using a negative voltage generator of the memory device illustrated in FIG. 7 according to example embodiments.

Referring to FIG. 7, the memory device 1100 may include a first memory cell MC1, a column selection circuit 1130, a first write driver 1141, and a negative voltage generator 2000. The first write driver 1141 may provide data signal DATA input through a first input/output line IO1 to the first memory cell MC1. The column selection circuit 1130 may connect the first bit line BL1 and the first complementary bit line BLB1 to the first write driver 1141. The first write driver 1141 may float one of the first bit line and the first complementary bit line BL1 and BLB1 in response to the data signal DATA and apply a write voltage to the remaining bit line. For example, when the data signal DATA is a logic high state signal, the first bit line BL1 may be floated and a write voltage may be applied to the first complementary bit line BLB1. Here, the voltage level of the floating bit line may be the logic high voltage, and the write voltage level may be the logic low voltage.

The negative voltage generator 2000 may generate a negative voltage VSSN in response to the control signal NBL_ENB. The control signal NBL_ENB may be provided from the control logic circuit (see FIGS. 5, 1160). The negative voltage generator 2000 may provide the negative voltage VSSN to the first write driver 1141. Here, the negative voltage VSSN may be a negative voltage lower than the write voltage which is the logic low voltage. The generated negative voltage VSSN may be additionally supplied to the bit line to which the write voltage is applied through the first write driver 1141.

Referring to FIG. 8, the first memory cell MC1 may include a latch circuit and first and second pass gates PG and PGB. The latch circuit may include first and second inverters INV1 and INV2 connected between first and second nodes N1 and N2. The first pass gate PG may be connected between the first node N1 and the first bit line BL1, and the second pass gate PGB may be connected between the second node N2 and the first complementary bit line BLB1.

The first write driver 1141 may include third to fifth inverters INV3, INV4, and INV5. The third inverter INV3 may be connected between a third node N3 and a fourth node N4. The third node N3 may receive a data signal DATA through the first input/output line IO1. The third inverter INV3 may provide inverted data /ATA to the fourth node N4.

The fourth inverter INV4 may be connected between the first bit line BL1 and the third node N3. The fourth inverter INV4 may include a first p-type metal-oxide-semiconductor (PMOS) transistor PM1 and a first n-type metal-oxide-semiconductor (NMOS) transistor NM1. The first PMOS transistor PM1 may be a pull-up transistor, and the first NMOS transistor NM1 may be a pull-down transistor.

The first PMOS transistor PM1 may be connected between a power terminal to which a power supply voltage (or internal high voltage) is supplied and the first bit line BL1, and may be controlled according to a voltage level of the third node N3. For example, the first PMOS transistor PM1 may include a source connected to the power terminal, a drain connected to the first bit line BL1, and a gate connected to the first input/output line IO1. For example, the first PMOS transistor PM1 may be turned off when the voltage level of the third node N3 is the logic high voltage, and may be turned on when the voltage level of the third node N3 is the logic low voltage. The first NMOS transistor NM1 may be connected between the first bit line BL1 and a fifth node N5, and may be controlled according to a voltage level of the third node N3. For example, the first NMOS transistor NM1 may include a source connected to the fifth node N5, a drain connected to the first bit line BL1, and a gate connected to the first input/output line IO1. For example, the first NMOS transistor NM1 may be turned on when the voltage level of the third node N3 is the logic high voltage, and may be turned off when the voltage level of the third node N3 is the logic low voltage. The fourth inverter INV4 may receive a first negative voltage VSSNa from the negative voltage generator 2000 through a fifth node N5.

Herein, a voltage level of the logic low voltage for each of the write voltage level, the bit line BL/the complementary bit line BLB, the data node Q/QB, data signal DATA, and the internal nodes of the SRAM or the memory device may be the same as or different from each other, and a voltage level of the logic high voltage for each of the write voltage level, the bit line BL/the complementary bit line BLB, the data node Q/QB, the data signal DATA, and the internal nodes of the SRAM or the memory device may be the same as or different from each other.

The fifth inverter INV5 may be connected between the first complementary bit line BLB1 and the fourth node N4. The fifth inverter INV5 may include a second PMOS transistor PM2 and a second NMOS transistor NM2. The second PMOS transistor PM2 may be a pull-up transistor, and the second NMOS transistor NM2 may be a pull-down transistor.

The second PMOS transistor PM2 may be connected between the power terminal and the first complementary bit line BLB1, and may be controlled according to a voltage level of the fourth node N4. For example, the second PMOS transistor PM2 may be turned off when the voltage level of the fourth node N4 is the logic high voltage, and may be turned on when the voltage level of the fourth node N4 is the logic low voltage. The second NMOS transistor NM2 may be connected between the first complementary bit line BLB1 and a sixth node N6, and may be controlled according to the voltage level of the fourth node N4. For example, the second NMOS transistor NM2 may be turned on when the voltage level of the fourth node N4 is the logic high voltage, and may be turned off when the voltage level of the fourth node N4 is the logic low voltage. The fifth inverter INV5 may receive a second negative voltage VSSNb from the negative voltage generator 2000 through a sixth node N6.

The negative voltage generator 2000 may provide the first negative voltage VSSNa to the fourth inverter INV4 of the first write driver 1141. The negative voltage generator 2000 may include a third NMOS transistor NM3 and a first delay circuit DLY1. The third NMOS transistor NM3 may be connected between the fifth node N5 and a ground terminal to which the ground voltage supplied and may be controlled according to a voltage level of a seventh node N7. A first coupling capacitor Ca may have a first end connected to the fifth node N5 and a second end connected to the first delay circuit DLY1. A voltage on the first end of the first coupling capacitor Ca may be the first negative voltage VSSNa and a voltage on the second end of the first coupling capacitor Ca may be a first positive voltage VSSPa. The first delay circuit DLY1 may receive the control signal NBL_ENB from the control logic circuit 1160 (see FIG. 5) through the seventh node N7, and output a delayed control signal as the first positive voltage VSSPa based on the control signal NBL_ENB.

In addition, the negative voltage generator 2000 may provide the second negative voltage VSSNb to the fifth inverter INV5 of the first write driver 1141. The negative voltage generator 2000 may include a fourth NMOS transistor NM4 and a second delay circuit DLY2. The fourth NMOS transistor NM4 may be connected between the sixth node N6 and the ground terminal and may be controlled according to a voltage level of an eighth node N8. A second coupling capacitor Cb may have a first end connected to the sixth node N6 and a second end connected to the second delay circuit DLY2. A voltage on the first end of the second coupling capacitor Cb may be the second negative voltage VSSNb and a voltage on the second end of the second coupling capacitor Cb may be a second positive voltage VSSPb. The second delay circuit DLY2 may receive the control signal NBL_ENB from the control logic circuit 1160 (see FIG. 5) through the eighth node N8, and output a delayed control signal as the second positive voltage VSSPb based on the control signal NBL_ENB.

Although the negative voltage generator 2000 including two delay circuits DLY1 and DLY2, two NMOS transistors NM3 and NM4, and two coupling capacitors Ca and Cb is shown in FIG. 8, the negative voltage generator 2000 may include one of the delay circuits DLY1 and DLY2, one of the NMOS transistors NM3 and NM4, and one of the coupling capacitors Ca and Cb.

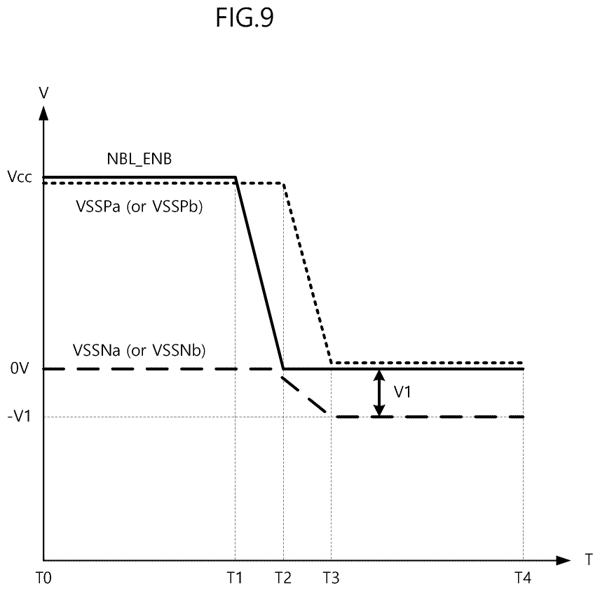

FIG. 9 is a timing diagram illustrating a negative voltage level of the memory device illustrated in FIG. 8 according to example embodiments. In FIG. 9, an abscissa denotes time T and an ordinate denotes a voltage level V.

In a time period from a time point T0 to a time point T1, the control signal NBL_ENB may be at a power supply voltage level Vcc. The control signal NBL_ENB having a power supply voltage level Vcc may be provided to the seventh and eighth nodes N7 and N8. Since the control signal NBL_ENB has the power supply voltage level Vcc, the third and fourth NMOS transistors NM3 and NM4 may be turned on.

When the third and fourth NMOS transistors NM3 and NM4 are turned on, the voltage levels of the fifth and sixth nodes N5 and N6 may be the ground voltage or 0V. Accordingly, the first and second negative voltages VSSNa and VSSNb may be 0V. For example, since the control signal NBL_ENB is the power supply voltage level Vcc, the first and second positive voltages VSSPa and VSSPb may be the power supply voltage level.

In a time period from the time point T1 to a time point T2, the control signal NBL_ENB may be lowered from the power supply voltage level Vcc to the ground voltage level. When the control signal NBL_ENB falls to the ground voltage level, the third and fourth NMOS transistors NM3 and NM4 may be turned off. When the third and fourth NMOS transistors NM3 and NM4 are turned off, the fifth and sixth nodes N5 and N6 may be in a floating state.

In a time period from the time point T2 to a time point T3, the control signal NBL_ENB may maintain the ground voltage level. The first and second positive voltages VSSPa and VSSPb may fall to the ground voltage level after being delayed by the time period from the time point T1 to the time point T2 due to the first and second delay circuits DLY1 and DLY2. When the first and second positive voltages VSSPa and VSSPb fall to the ground voltage level, the first and second negative voltages VSSNa and VSSNb may have a first negative voltage level (e.g., −V1) due to capacitive coupling.

In a time period from a time point T3 to a time point T4, the first and second negative voltages VSSNa and VSSNb having the first negative voltage level (e.g., −V1) may be provided to the first write driver 1141. The first negative voltage VSSNa may be provided to the first NMOS transistor NM1 of the fourth inverter INV4. The second negative voltage VSSNb may be provided to the second NMOS transistor NM2 of the fifth inverter INV5.

Referring again to FIG. 8, the first and second coupling capacitors Ca and Cb may be implemented in various ways. For example, the first and second coupling capacitors Ca and Cb may be capacitors located on a metal line connecting the negative voltage generator 2000 and the first write driver 1141. In addition, each of the first and second coupling capacitors Ca and Cb may be a MOS capacitor using a MOS transistor.

The capacitance of the first and second coupling capacitors Ca and Cb may increase as the area of the capacitors becomes larger or the gap between the capacitors becomes narrower. When the capacitance of the first and second coupling capacitors Ca and Cb increases, the capacitive coupling effect may increase. A higher negative voltage may be generated in the negative direction. Hereinafter, various methods for increasing the capacitance of the coupling capacitors will be described.

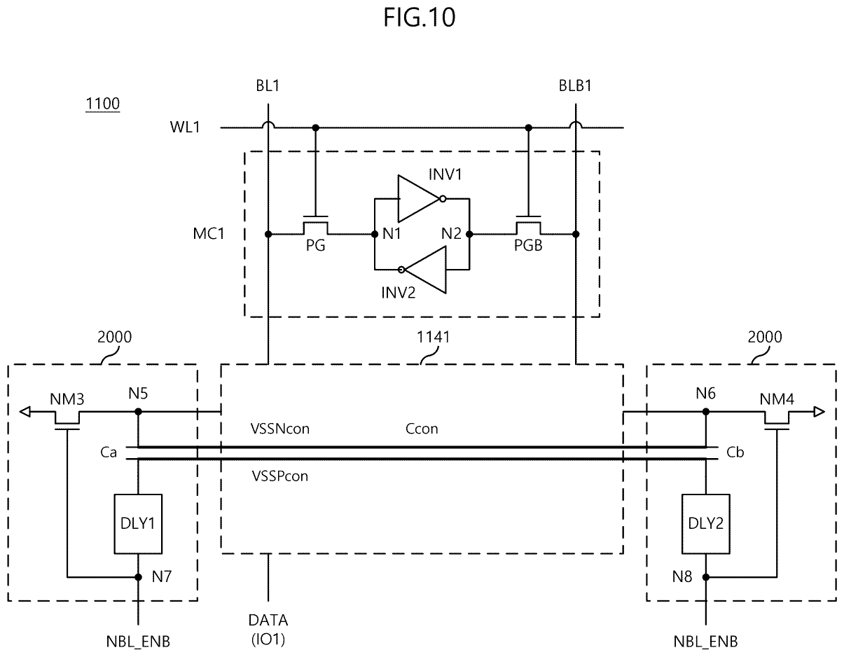

FIG. 10 is a block diagram illustrating a memory device according to an example embodiment of the present disclosure. Referring to FIG. 10, the memory device 1100 may include a first memory cell MC1, a first write driver 1141, and a negative voltage generator 2000. The first memory cell MC1 may be, for example, an SRAM cell.

The memory device 1100 illustrated in FIG. 10 has the same configuration and operating principle as the first memory cell MC1, the first write driver 1141, and the negative voltage generator 2000 illustrated in FIG. 8. However, the negative voltage generator 2000 of the memory device 1100 illustrated in FIG. 10 may electrically connect the first coupling capacitor Ca to the second coupling capacitor Cb illustrated in FIG. 8 using a metal line or a conductive line. The negative voltage generator 2000 may have a connection coupling capacitor Ccon by connecting the first and second coupling capacitors Ca and Cb. For example, the first ends of the first and second coupling capacitors Ca and Cb connected to one another through a first metal line may be connected to the fifth and sixth nodes N5 and N6, and the second ends of the first and second coupling capacitors Ca and Cb connected to one another through a second metal line may be connected to the first and second delay circuits DLY1 and DLY2. In example embodiments, the first metal line and the second metal line may be formed in the same metal layer (or in the same vertical level) or a different metal layer (or in a different vertical level). A voltage on the first ends of the first and second coupling capacitors Ca and Cb may be a connection coupling negative voltage VSSNcon and a voltage on the second ends of the first and second coupling capacitors Ca and Cb may be a connection coupling positive voltage VSSPcon.

The capacitance of the connection coupling capacitor Ccon may be higher than that of each of the first and second coupling capacitors Ca and Cb. The connection coupling capacitor Ccon may obtain the effect of increasing the area of the connection coupling capacitor by connecting the first end of the first coupling capacitor Ca to the first end of the second coupling capacitor Cb using the first metal line and by connecting the second end of the first coupling capacitor Ca to the second end of the second coupling capacitor Cb using the second metal line. The negative voltage generator 2000 of FIG. 10 may generate a higher negative voltage in the negative direction due to the higher capacitive coupling effect.

In an embodiment, an insulating layer may be formed between the first metal line connected to the first ends of the first and second coupling capacitors Ca and Cb and the second metal line connected to the second ends of the first and second coupling capacitors Ca and Cb. For example, the first metal line and the second metal line may be overlapped in a vertical direction or a horizontal direction and the capacitance may increase when the overlapping area increases.

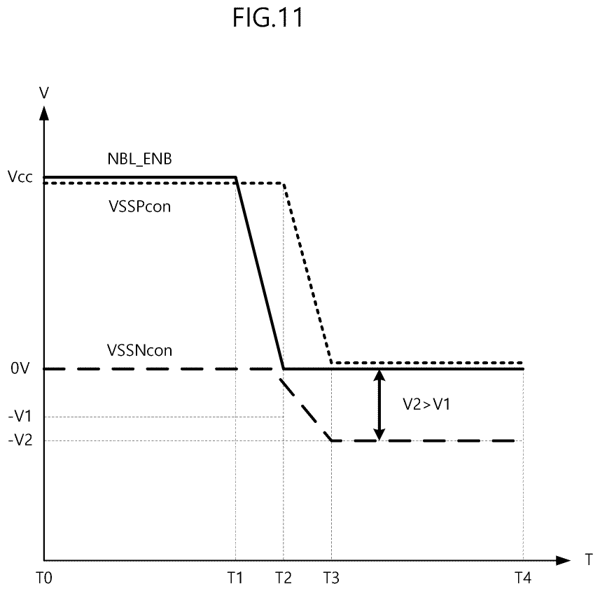

FIG. 11 is a timing diagram illustrating the negative voltage level of the memory device illustrated in FIG. 10 according to example embodiments.

In the time period from the time point T0 to the time point T1, the control signal NBL_ENB may be at the power supply voltage level Vcc. Since the control signal NBL_ENB has the power supply voltage level Vcc, the third and fourth NMOS transistors NM3 and NM4 may be turned on. Accordingly, the connection coupling negative voltage VSSNcon may be 0V, and the connection coupling positive voltage VSSPcon may be the power supply voltage level.

In the time period from the time point T1 to the time point T2, the control signal NBL_ENB may be lowered from the power supply voltage level Vcc to the ground voltage level (e.g., 0V). When the control signal NBL_ENB drops to the ground voltage level, the third and fourth NMOS transistors NM3 and NM4 may be turned off. When the third and fourth NMOS transistors NM3 and NM4 are turned off, the fifth and sixth nodes N5 and N6 may be in a floating state.

In the time period from the time point T2 to the time point T3, the control signal NBL_ENB may maintain the ground voltage level. The connection coupling positive voltage VSSPcon may drop to the ground voltage level, and the connection coupling negative voltage VSSNcon may have a second negative voltage level (e.g., −V2) due to capacitive coupling. Here, an absolute voltage level of V2 may be greater than an absolute voltage level of V1 of FIG. 9. The negative voltage generator 2000 of FIG. 10 may have a connection coupling capacitor Ccon that connects the first and second coupling capacitors Ca and Cb with a metal line or a conductive line. A higher negative voltage may be generated in the negative direction due to a higher capacitive coupling effect.

In the time period from the time point T3 to the time point T4, the connection coupling negative voltage VSSNcon having the second negative voltage level (e.g., −V2) may be provided to the first write driver 1141. The third negative voltage VSSNcon may be provided to the first NMOS transistor NM1 of the fourth inverter INV4 and the second NMOS transistor NM2 of the fifth inverter INV5.

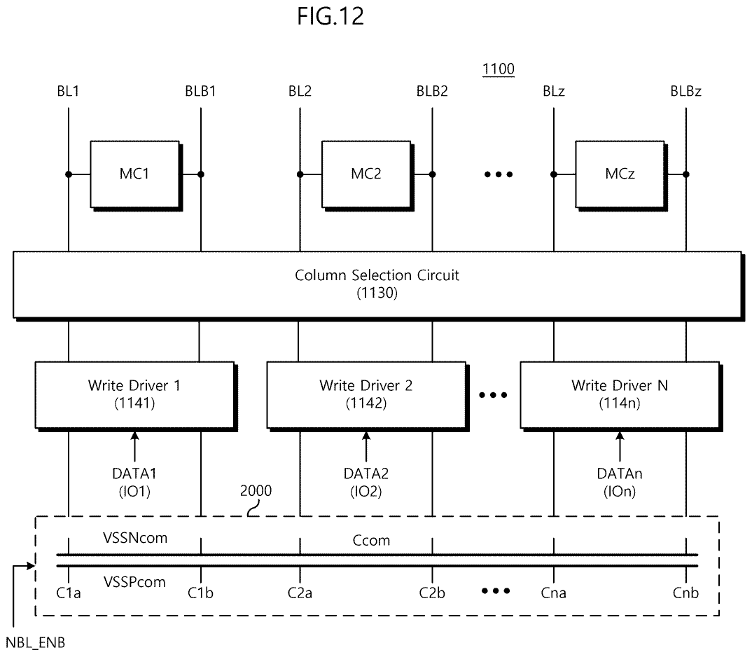

FIG. 12 is a block diagram illustrating a memory device according to example embodiments of the present disclosure. Referring to FIG. 12, the memory device 1100 may include first to z-th memory cells MC1 to MCz, a column selection circuit 1130, first to n-th write drivers 1141 to 114n, and a negative voltage generator 2000. Each of the first to z-th memory cells MC1 to MCz may be, for example, an SRAM cell.

The write drivers 1141 to 114n and the negative voltage generator 2000 illustrated in FIG. 12 may have the same configuration and operating principle as those illustrated in FIG. 8. However, the negative voltage generator 2000 illustrated in FIG. 12 may electrically share capacitors C1a, C1b, C2a, C2b, . . . , Cna, and Cnb with metal lines or conductive lines. The capacitors C1a, C1b, C2a, C2b, . . . , Cna, and Cnb may be located adjacent to each other in the direction in which the input/output lines IO1 to IOn are arranged. The negative voltage generator 2000 may have a shared coupling capacitor Ccom by connecting the capacitors C1a, C1b, C2a, C2b, . . . , Cna, and Cnb. For example, first ends of the capacitors C1a, C1b, C2a, C2b, . . . , Cna, and Cnb may be connected to the write drivers 1141 to 114n through a metal line, and second ends of the capacitors C1a, C1b, C2a, C2b, . . . , Cna, and Cnb may be connected to the first to nth delay circuits DLY1 and DLYn through a metal line. A voltage on the first ends of the capacitors C1a, C1b, C2a, C2b, . . . , Cna, and Cnb may be a shared coupling negative voltage VSSNcom and a voltage on the second ends of the capacitors C1a, C1b, C2a, C2b, . . . , Cna, and Cnb may be a shared coupling positive voltage VSSPcom. In an embodiment, the negative voltage generator 2000 may include only some of capacitors C1a, C1b, C2a, C2b, . . . , Cna, and Cnb. For example, the negative voltage generator 2000 may include four capacitors C1a, C2a, C3a, and C4a.

The capacitance of the shared coupling capacitor Ccom may be greater than the connected coupling capacitor Ccon illustrated in FIG. 10. The shared coupling capacitor Ccom may obtain the effect of increasing the area of the capacitors by connecting the capacitors C1a, C1b, C2a, C2b, . . . , Cna, and Cnb with a metal line or a conductive line. The negative voltage generation circuit 2000 of FIG. 12 may generate a higher negative voltage in the negative direction due to the higher capacitive coupling effect.

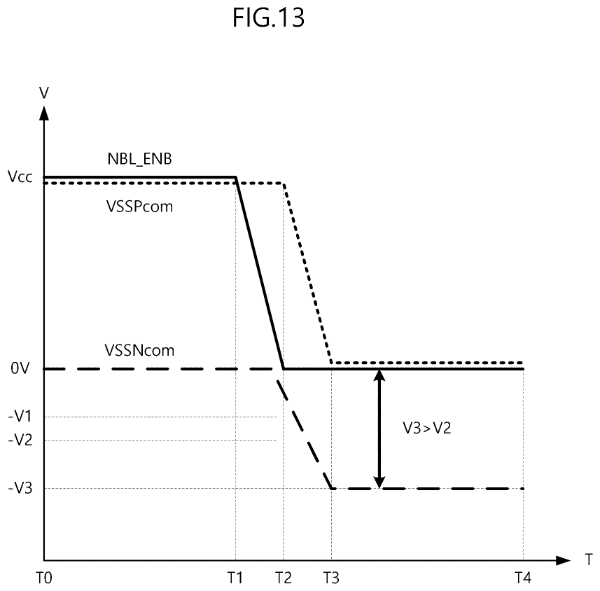

FIG. 13 is a timing diagram illustrating the negative voltage level of the memory device illustrated in FIG. 12 according to example embodiments.

In the time period from the time point T0 to the time point T1, the control signal NBL_ENB may be at the power supply voltage level Vcc. Since the control signal NBL_ENB has the power supply voltage level Vcc, the shared coupling negative voltage VSSNcom is 0V, and the shared coupling positive voltage VSSPcom may be the power supply voltage level.

In the time period from the time point T1 to the time point T2, the control signal NBL_ENB may fall from the power supply voltage level Vcc to the ground voltage level. When the control signal NBL_ENB falls to the ground voltage level, the shared coupling negative voltage VSSNcom may be in a floating state.

In the time period from the time point T2 to the time point T3, the control signal NBL_ENB may maintain the ground voltage level. The shared coupling positive voltage VSSPcom may be lowered to the ground voltage level. By capacitive coupling, the shared coupling negative voltage VSSNcom may have a third negative voltage level (e.g., −V3). Here, an absolute voltage level of V3 may be greater than the absolute voltage level of V2. The negative voltage generator 2000 of FIG. 12 may have the shared coupling capacitor Ccom that connects the capacitors C1a, C1b, C2a, C2b, . . . , Cna, and CnB with a metal line or a conductive line. Due to the higher capacitive coupling effect, a higher negative voltage may be generated in the negative direction.

In the time period from the time point T3 to the time point T4, the shared coupling negative voltage VSSNcom having the third negative voltage (e.g., −V3) may be provided to the first to n-th write drivers 1141 to 114n.

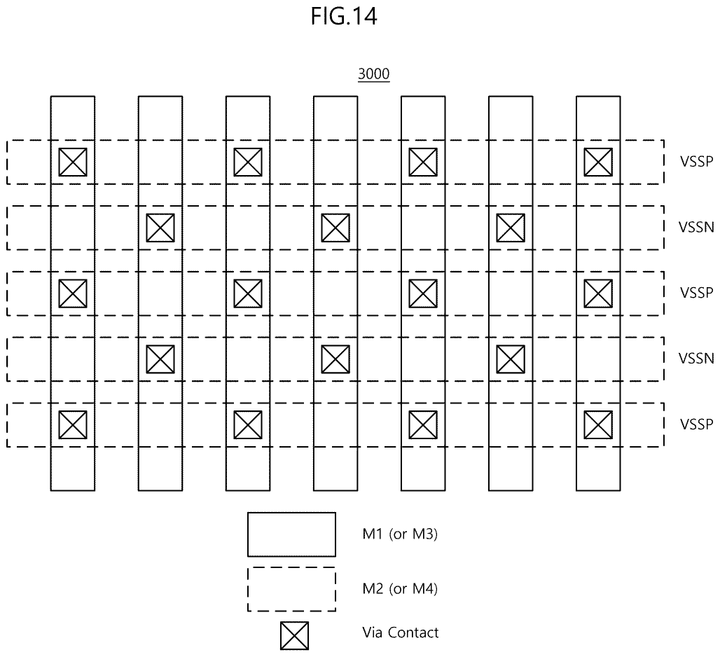

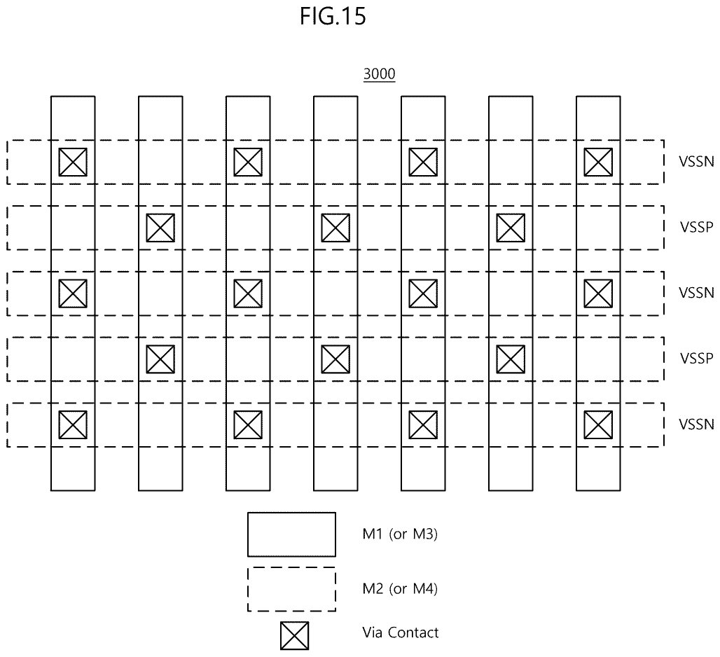

FIG. 14 and FIG. 15 are layout diagrams illustrating a memory device according to example embodiments of the present disclosure. Referring to FIGS. 14 and 15, the memory device 3000 may electrically connect capacitors through via contacts and metal layers (or metal lines). In FIGS. 14 and 15, a solid line may be a first metal layer M1 or a third metal layer M3, and a dotted line may be a second metal layer M2 or a fourth metal layer M4. Herein, the via contact may electrically connect different metal layers to one another. For example, the first metal layer M1 may be connected to the second metal layer M2 through the via contact.

The memory device 3000 may connect different metal layers within a semiconductor chip using the via contacts. A manufacturing process of the via contacts may be performed in the following steps. First, an interlayer insulating layer may be formed. An insulating layer may be formed between metal layers to prevent electrical interference and to increase capacitance. Next, a via hole may be formed. A small hole may be made in the insulating layer to create a via hole. Next, a metal may be deposited. The via hole may be filled with a metal to electrically connect the different metal layers. For example, tungsten W or copper Cu may be used as the metal. Next, a planarization CMP operation may be performed. After the metal is filled, the surface may be made flat and the next process may be prepared.

The negative voltage generator (not shown) of the memory device 3000 may have a via coupling capacitor Cvia through a via contact. The capacitance of the via coupling capacitor Cvia may be higher than the shared coupling capacitor Ccom illustrated in FIG. 12. The via coupling capacitor Cvia may obtain the effect of increasing the area of the capacitor by connecting metal lines or conductive lines. in different layers through the via contacts. For example, the via coupling capacitor Cvia may be formed between the first metal layer M1 and the second metal layer M2 in a vertical direction and/or in a horizontal direction, and formed between adjacent via contacts in the horizontal direction. The negative voltage generation circuit (not shown) of FIGS. 14 and 15 may generate a higher negative voltage in the negative direction due to a higher capacitive coupling effect.

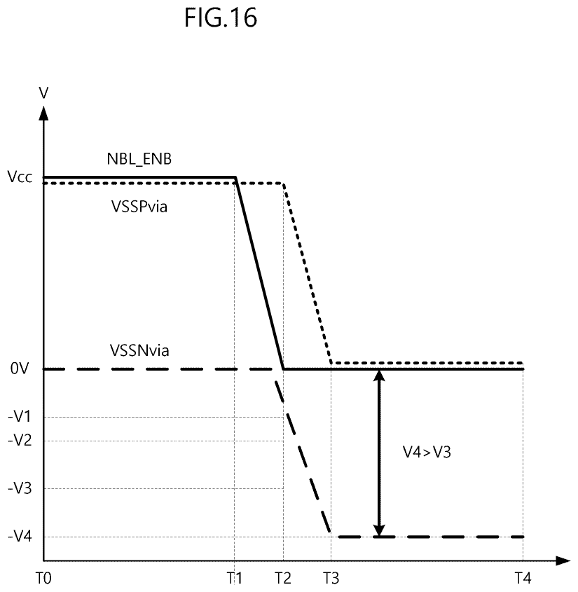

FIG. 16 is a timing diagram illustrating a negative voltage level of the memory device illustrated in FIGS. 14 and 15 according to example embodiments.

In the time period from the time point T0 to the time point T1, the control signal NBL_ENB may be at the power supply voltage level Vcc. Since the control signal NBL_ENB has the power supply voltage level Vcc, a via negative voltage VSSNvia is 0V, and a via positive voltage VSSPvia may be the power supply voltage level.

In the time period from the time point T1 to the time point T2, the control signal NBL_ENB may fall from the power supply voltage level Vcc to the ground voltage level. When the control signal NBL_ENB falls to the ground voltage level, the via negative voltage VSSNvia may be in a floating state.

In the time period from the time point T2 to the time point T3, the control signal NBL_ENB may maintain the ground voltage level. The via positive voltage VSSPvia falls to the ground voltage level, and the via negative voltage VSSNvia may have a fourth negative voltage level (e.g., −V4) by capacitive coupling. Here, an absolute voltage level of V4 may be greater than an absolute voltage level of V3 of FIG. 13. The memory device 3000 of FIGS. 14 and 15 has the via coupling capacitor Cvia that connects metal lines using via contacts. Due to the higher capacitive coupling effect, a higher negative voltage may be generated in the negative direction.

In the time period from the time point T3 to the time point T4, the via negative voltage VSSNvia having the fourth negative voltage level (e.g., −V4) may be provided to write drivers (not shown).

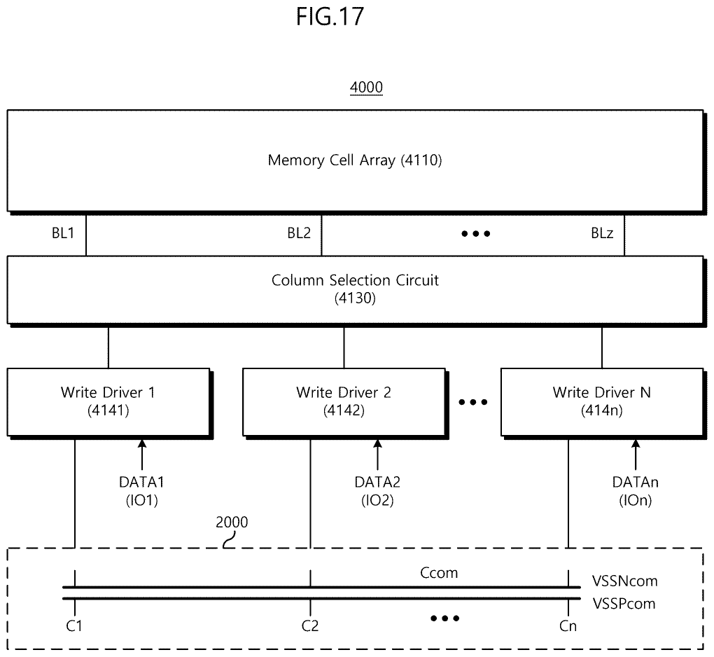

FIG. 17 is a block diagram illustrating a memory device according to example embodiments of the present disclosure. A memory device 4000 may be a memory device, for example, a dynamic random access memory (DRAM) device.

Referring to FIG. 17, the memory device 4000 may include a memory cell array 4110, a column selection circuit 4130, first to n-th write drivers 4141 to 414n, and a negative voltage generator 2000. The negative voltage generator 2000 illustrated in FIG. 17 may increase the capacitive coupling effect by electrically sharing the first to nth capacitors C1 to Cn with metal lines or conductive lines. The negative voltage generator 2000 may have a shared coupling capacitor Ccom. In an embodiment, the shared coupling capacitor Ccom of FIG. 17 may correspond to the shared coupling capacitor Ccom of FIG. 12. In an embodiment, the negative voltage generator 2000 may include only some of capacitors C1 to Cn. For example, the negative voltage generator 2000 may include only two capacitors C1 and C2.

According to the present disclosure, it may be possible to generate a higher negative voltage in the negative direction due to a high capacitive coupling effect by electrically connecting coupling capacitors included in a negative voltage generator using a metal line or the like. According to the present disclosure, a stable write operation may be performed.

While the present disclosure has been described with reference to embodiments thereof, it will be apparent to those of ordinary skill in the art that various changes and modifications may be made thereto without departing from the spirit and scope of the present invention as set forth in the following claims.

What is claimed is:

1. A memory device comprising:
first and second memory cells;
a first write driver configured to provide write data to the first memory cell;
a second write driver configured to provide write data to the second memory cell; and
a negative voltage generator configured to provide a negative voltage to the first and second write drivers,
wherein the negative voltage generator includes:
a first coupling capacitor configured to provide the negative voltage to the first write driver; and
a second coupling capacitor configured to provide the negative voltage to the second write driver, and
wherein the first and second coupling capacitors are electrically connected to one another.

2. The memory device of claim 1, wherein each of the first and second coupling capacitors includes a first end and a second end opposite to the first end,
wherein the first ends of the first and second coupling capacitors are electrically connected to one another through a metal line, and
wherein the second ends of the first and second coupling capacitors are electrically connected to one another through a metal line.

3. The memory device of claim 1, wherein the first and second coupling capacitors are located adjacent to each other in a direction in which input/output lines are arranged.

4. The memory device of claim 1, wherein each of the first and second write drivers includes:
a pull-up transistor including a source connected to a power terminal and a drain; and
a pull-down transistor including a drain connected to the drain of the pull-up transistor and a source configured to receive the negative voltage from the negative voltage generator.

5. The memory device of claim 4, wherein the pull-up transistor and the pull-down transistor for each of the first and second write drivers are configured to form an inverter.

6. The memory device of claim 4, wherein the negative voltage generator further includes an n-type metal-oxide-semiconductor (NMOS) transistor connected between a first end of each of the first and second coupling capacitors and a ground terminal, and
wherein the NMOS transistor is configured to provide a ground voltage to the source of the pull-down transistor of each of the first and second write drivers or make it floating, in response to a control signal.

7. The memory device of claim 6, wherein the negative voltage generator further includes a delay circuit connected to a second end of each of the first and second coupling capacitors, and
wherein the delay circuit is configured to provide a delayed control signal to the second end of each of the first and second coupling capacitors.

8. The memory device of claim 1, wherein each of the first and second coupling capacitors includes a first end and a second end opposite to the first end,
wherein the first ends of the first and second coupling capacitors are electrically connected to one another through metal lines and via contacts, and
wherein the second ends of the first and second coupling capacitors are electrically connected to one another through metal lines and via contacts.

9. The memory device of claim 1, wherein each of the first and second coupling capacitors includes a metal-oxide-semiconductor (MOS) capacitor.

10. The memory device of claim 1, wherein each of the first and second memory cells includes a static random access memory cell.

11. A memory device comprising:
a memory cell;
a first bit line connected to the memory cell;
a second bit line connected to the memory cell;
a write driver including a first inverter configured to provide write data to the memory cell through the first bit line and a second inverter configured to provide write data to the memory cell through the second bit line; and
a negative voltage generator configured to provide a negative voltage to the write driver,
wherein the negative voltage generator includes:
a first coupling capacitor configured to provide the negative voltage to the first inverter; and
a second coupling capacitor configured to provide the negative voltage to the second inverter, and
wherein the first and second coupling capacitors are electrically connected to one another.

12. The memory device of claim 11, wherein each of the first and second coupling capacitors includes a first end and a second end opposite to the first end,
wherein the first ends of the first and second coupling capacitors are electrically connected to one another through a metal line, and
wherein the second ends of the first and second coupling capacitors are electrically connected to one another through a metal line.

13. The memory device of claim 11, wherein each of the first and second inverters includes:
a pull-up transistor including a source connected to a power terminal and a drain; and
a pull-down transistor including a drain connected to the drain of the pull-up transistor and a source configured to receive the negative voltage from the negative voltage generator.

14. The memory device of claim 13,
wherein the negative voltage generator further includes an n-type metal-oxide-semiconductor (NMOS) transistor connected between a first end of each of the first and second coupling capacitors and a ground terminal, and
wherein the NMOS transistor is configured to provide a ground voltage to the source of the pull-down transistor of each of the first and second write drivers or make it a floating state, in response to a control signal.

15. The memory device of claim 14,
wherein the negative voltage generator further includes a delay circuit connected to a second end of each of the first and second coupling capacitors, and
wherein the delay circuit is configured to provide a delayed control signal to the second end on each of the first and second coupling capacitors.

16. A memory device comprising:
first and second memory cells;
first and second bit lines connected to the first memory cell;
third and fourth bit lines connected to the second memory cell;
a first write driver including a first inverter configured to provide write data to the first memory cell through the first bit line, and a second inverter configured to provide write data to the first memory cell through the second bit line;
a second write driver including a third inverter configured to provide write data to the second memory cell through the third bit line, and a fourth inverter configured to provide write data to the second memory cell through the fourth bit line; and
a negative voltage generator configured to provide a negative voltage to the first and second write drivers,
wherein the negative voltage generator includes:
a first coupling capacitor configured to provide the negative voltage to the first inverter;
a second coupling capacitor configured to provide the negative voltage to the second inverter;
a third coupling capacitor configured to provide the negative voltage to the third inverter; and
a fourth coupling capacitor configured to provide the negative voltage to the fourth inverter, and
wherein the first to fourth coupling capacitors are electrically connected to one another.

17. The memory device of claim 16, wherein each of the first to fourth coupling capacitors includes a first end and a second end opposite to the first end,
wherein the first ends of the first to fourth coupling capacitors are electrically connected to one another via a metal line, and
wherein the second ends of the first to fourth coupling capacitors are electrically connected to one another via a metal line.

18. The memory device of claim 16, wherein each of the first to fourth inverters includes,
a pull-up transistor including a source connected to a power terminal and a drain; and
a pull-down transistor including a drain connected to the drain of the pull-up transistor and a source configured to receive the negative voltage from the negative voltage generator.

19. The memory device of claim 18, wherein the negative voltage generator further includes n-type metal-oxide-semiconductor (NMOS) transistors each connected between a first end of each of the first to fourth coupling capacitors and a ground terminal, and
wherein each of the NMOS transistors is configured to provide a ground voltage to the source of the pull-down transistor of each of the first to fourth inverters or make it a floating state, in response to a control signal.

20. The memory device of claim 19, wherein the negative voltage generator further includes delay circuits each connected to a second end of each of the first to fourth coupling capacitors, and
wherein each of the delay circuits is configured to provide a delayed control signal to the second end of each of the first to fourth coupling capacitors.
